(19) United States
(12) Patent Application Publication
(10) Pub. No.: US 2024/0373576 A1
(43) Pub. Date: Nov. 7, 2024

(54) HOLDING STRUCTURE AND HOLDING METHOD

(71) Applicant: SONY GROUP CORPORATION, TOKYO (JP)

(72) Inventors: MASAHARU SAKATA, TOKYO (JP); HIDEO MIYANO, TOKYO (JP)

(21) Appl. No.: 18/556,690

(22) PCT Filed: Feb. 16, 2022
(86) PCT No.: PCT/JP2022/006153

§ 371 Date: Oct. 23, 2023

(30) Foreign Application Priority Data
May 12, 2021 (JP) 2021-080971

(51) Int. Cl. H05K 7/14; G01C 19/00

(52) U.S. Cl. CPC H05K 7/14; G01C 19/00

(57) ABSTRACT

A holding structure according to an embodiment of the present technology is a holding structure that is used to provide, to a target, a substrate on which an inertial sensor is arranged, and the holding structure includes at least two connection structure portions. The at least two connection structure portions are respectively provided to at least two portions of the substrate, and connects the substrate to the target. Further, the at least two connection structure portions each have a bonding structure obtained by an adhesive material being provided between the target and substrate being spaced from each other; or one of the at least two connection structure portions has a pressing structure obtained by the substrate being pressed against the target to be fixed to the target, and another of the at least two connection structure portions has the bonding structure.

### TECHNICAL FIELD

The present technology relates to a holding structure and a holding method that can be applied when an inertial sensor is placed.

### BACKGROUND ART

Patent Literature 1 discloses a vibration isolation system for an inertial sensor. This vibration isolation system includes an elastomeric member arranged around the inertial sensor. This makes it possible to prevent the inertial sensor from being affected by vibrational, shock, and acoustic energy (for example, paragraphs and of the specification and FIG. 7 in Patent Literature 1).

### CITATION LIST

### Patent Literature

Patent Literature 1: Japanese Unexamined Patent Application Publication No. 2005-504251

### DISCLOSURE OF INVENTION

### Technical Problem

There is a need for a technology that makes it possible to improve the accuracy in measurement performed by an inertial sensor, as described above.

In view of the circumstances described above, it is an object of the present technology to provide a holding structure and a holding method that make it possible to improve the accuracy in measurement performed by an inertial sensor.

### Solution to Problem

In order to achieve the object described above, a holding structure according to an embodiment of the present technology is a holding structure that is used to provide, to a target, a substrate on which an inertial sensor is arranged, and the holding structure includes at least two connection structure portions.

The at least two connection structure portions are respectively provided to at least two portions of the substrate, and connects the substrate to the target.

Further, the at least two connection structure portions each have a bonding structure obtained by an adhesive material being provided between the target and substrate being spaced from each other; or one of the at least two connection structure portions has a pressing structure obtained by the substrate being pressed against the target to be fixed to the target, and another of the at least two connection structure portions has the bonding structure.

In this holding structure, at least two connection structure portions used to connect a substrate to a target are respectively provided to at least two portions of the substrate. The at least two connection structure portions each have a bonding structure obtained by an adhesive material being provided between the target and substrate being spaced from each other. Alternatively, one of the at least two connection structure portions has a pressing structure obtained by the substrate being pressed against the target to be fixed to the target, and another of the at least two connection structure portions has the bonding structure. This makes it possible to improve the accuracy in measurement performed by an inertial sensor.

The pressing structure may include a structure obtained by the substrate being fixed to the target through a fastening member.

The fastening member may be a screw.

The pressing structure may include a structure obtained by the substrate being sandwiched using the target to be fixed to the target.

The target may include a first fixation portion and a second fixation portion between which the substrate is sandwiched to be fixed to the target. In this case, at least one of the first fixation portion or the second fixation portion may fix the substrate to the target through an elastic body.

The bonding structure may include a structure obtained by the adhesive material being provided on the basis of a position of a hole of the target in a state in which an insertion portion of the substrate is inserted into the hole.

The hole may be a through hole.

The adhesive material may be provided to cover at least a portion of an opening of the hole.

The hole may be filled with the adhesive material.

The bonding structure may include a structure obtained by the adhesive material being provided on the basis of a position of a hole of the substrate in a state in which an insertion portion of the target is inserted into the hole.

The at least two connection structure portions may each have the bonding structure.

One of the at least two connection structure portions may have the pressing structure, and another of the at least two connection structure portions may have the bonding structure.

The inertial sensor may be configured to include at least one of an acceleration sensor or an angular velocity sensor.

Respective positions of the at least two connection structure portions may be set on the basis of a position of the inertial sensor on the substrate.

A position of the inertial sensor may be set on the basis of respective positions of the at least two connection structure portions.

The inertial sensor may be arranged at a center of gravity obtained by using the respective positions of the at least two connection structure portions.

The holding structure may be configured such that the substrate is provided to a rotation section to be rotated integrally with the rotation section, the rotation section being the target, the rotation section being rotatable about a specified rotational axis. In this case, an image-capturing section may be provided to the rotation section to be rotated integrally with the rotation section.

A holding method according to an embodiment of the present technology is a holding method that is performed to provide, to a target, a substrate on which an inertial sensor is arranged, and the holding method includes connecting at least two portions of the substrate to the target using a bonding structure obtained by an adhesive material being provided between the target and substrate being spaced from each other.

A holding method according to an embodiment of the present technology is a holding method that is performed to provide, to a target, a substrate on which an inertial sensor is arranged, and the holding method includes connecting one of at least two portions of the substrate to the target using a pressing structure obtained by the substrate being pressed against the target to be fixed to the target.

Another of the at least two portions is connected to the target using a bonding structure obtained by an adhesive material being provided between the target and substrate being spaced from each other.

### BRIEF DESCRIPTION OF DRAWINGS

FIG. 1 is a perspective view illustrating an example of an appearance of an image-capturing apparatus.

FIG. 2 is a functional block diagram used to describe a basic operation of the image-capturing apparatus.

FIG. 3 is a side view of the image-capturing apparatus as viewed from a positive direction on a Z direction.

FIG. 4 is a side view of the image-capturing apparatus as viewed from a negative direction on a Y direction.

FIG. 5 is a cross-sectional view along the line B-B illustrated in FIG. 4.

FIG. 6 is a perspective view illustrating an internal configuration of the image-capturing apparatus.

FIG. 7 is a cross-sectional view along the line A-A illustrated in FIG. 3.

FIG. 8 schematically illustrates an overview of a holding structure.

FIG. 9 schematically illustrates a variation of a bonding structure.

FIG. 10 schematically illustrates a variation of the bonding structure.

FIG. 11 schematically illustrates a variation of the bonding structure.

FIG. 12 schematically illustrates a variation of the bonding structure.

FIG. 13 schematically illustrates a variation of the bonding structure.

FIG. 14 schematically illustrates an example of a pressing structure.

FIG. 15 schematically illustrates an example of the pressing structure.

FIG. 16 schematically illustrates an example of a configuration of arrangement of a connection structure portion.

FIG. 17 schematically illustrates an example of the configuration of the arrangement of the connection structure portion.

### MODE(S) FOR CARRYING OUT THE INVENTION

Embodiments according to the present technology will now be described below with reference to the drawings.

### [Overview of Image-Capturing Apparatus]

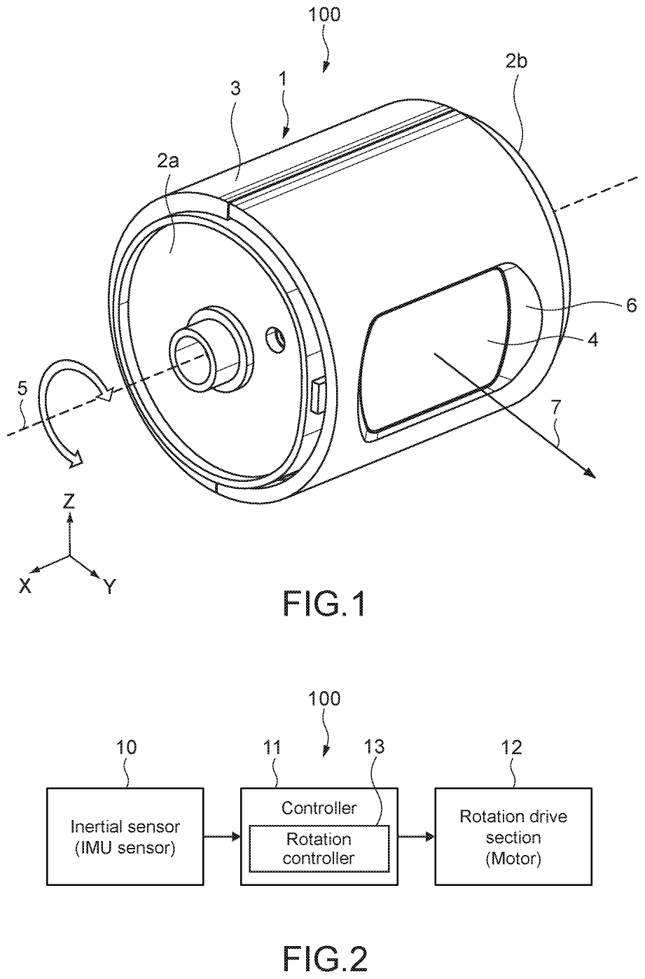

FIG. 1 is a perspective view illustrating an example of an appearance of an image-capturing apparatus according to the present embodiment.

As illustrated in FIG. 1, an image-capturing apparatus 100 has a substantially cylindrical shape. FIG. 1 illustrates the appearance of the image-capturing apparatus 100 such that a bottom 2a from between two bottoms 2 (2a and 2b) and a side 3 that are included in the image-capturing apparatus 100 are seen.

In the following description, a depth direction (a direction vertical to the bottom 2a of the image-capturing apparatus 100) when the bottom 2a is viewed from the front is referred to as an X direction, a right-and-left direction when the bottom 2a is viewed from the front is referred to as a Y direction, and an up-and-down direction when the bottom 2a is viewed from the front is referred to as a Z direction.

Further, a positive direction and a negative direction on the X direction illustrated in FIG. 1 may be respectively referred to as a front direction and a back direction. A positive direction and a negative direction on the Y direction may be respectively referred to as a right direction and a left direction. A positive direction and a negative direction on the Z direction may be respectively referred to as an upward direction and a downward direction.

Furthermore, a direction from which the image-capturing apparatus 100 is viewed may be represented using the expressions described above. For example, “viewing the image-capturing apparatus 100 from the positive direction on the X direction” means “viewing the image-capturing apparatus 100 from a tip of an arrow representing an X axis”.

Of course, in the application of the present technology, an orientation of the image-capturing apparatus 100 in use and the like are not limited.

The image-capturing apparatus 100 includes a rotation section 1 that is rotatable about a specified rotational axis.

In the present embodiment, the rotation section 1 includes the bottoms 2 (2a and 2b) and the side 3, and is rotatable about a rotational axis 5 that passes through a center of the bottom 2 to extend in parallel with the X direction.

The rotation section 1 can be rotated clockwise or counterclockwise about the rotational axis 5, as viewed from the X direction. FIG. 1 illustrates a thick arrow that indicates a rotation direction of the rotation section 1.

Further, the rotation section 1 can also serve as a housing of the image-capturing apparatus 100.

As illustrated in FIG. 1, a window 4 is provided to the side 3 of the rotation section 1.

Specifically, a concave portion 6 is provided to the side 3 of the rotation section 1, and the window 4 is arranged on a bottom surface of the concave portion 6. The window 4 is substantially rectangular, as viewed from the front. A shape of the window 4 is not limited.

The window 4 is a transparent member. Note that, in the present disclosure, “being transparent” includes not only “being completely transparent” but also “being semitransparent” and “being colored transparent”.

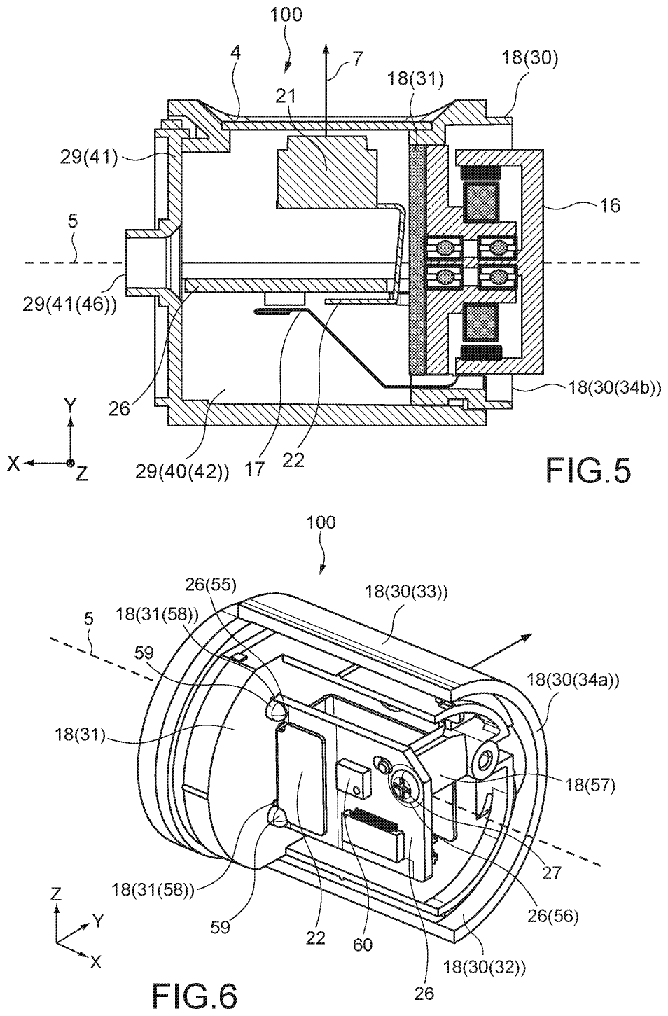

A camera module 21 (refer to FIG. 5) is provided inside of the rotation section 1 at a location at which the camera module 21 faces the window 4.

The camera module 21 is provided in the rotation section 1 such that an image-capturing direction 7 is oriented toward the outside of the rotation section 1. The camera module 21 is provided such that the image-capturing direction 7 is orthogonal to the window 4, as illustrated in FIG. 1.

Note that the image-capturing direction 7 corresponds to a direction of an image-capturing optical axis of the camera module 21.

The camera module 21 corresponds to an embodiment of an image-capturing section according to the present technology.

The camera module 21 is provided to the rotation section 1 to be rotated integrally with the rotation section 1. This will be described in detail later.

Thus, the image-capturing direction of the camera module 21 is changed according to a rotation of the rotation section 1.

For example, the control of the rotation of the rotation section 1 makes it possible to set the image-capturing direction of the camera module 21 discretionarily in all directions of 360 degrees by the camera module 21 being rotated about the rotational axis 5.

### [Control of Rotation]

FIG. 2 is a functional block diagram used to describe a basic operation of the image-capturing apparatus 100.

As illustrated in FIG. 2, the image-capturing apparatus 100 includes an inertial sensor 10, a controller 11, and a rotation drive section 12.

The inertial sensor 10 is a sensor that can measure inertial force. In the present embodiment, the inertial sensor 10 is configured to include at least one of an acceleration sensor or an angular velocity sensor. In the present embodiment, an inertial measurement unit (IMU) sensor is used as the inertial sensor 10. The IMU sensor is also referred to as an inertial measurement unit.

The IMU sensor can detect (sense) acceleration and angular velocity of the image-capturing apparatus 100. The IMU sensor can detect the acceleration and the angular velocity of the image-capturing apparatus 100 with respect to, for example, three axes that are orthogonal to each other.

Of course, only one of an acceleration sensor and an angular velocity sensor may be used as the inertial sensor 10.

Further, any configuration may be adopted as a specific configuration of the inertial sensor 10.

The controller 11 includes hardware, such as a CPU, a ROM, a RAM, and an HDD, that is necessary for a configuration of a computer. For example, processing related to, for example, control of rotation according to the present technology is performed by the CPU loading, into the RAM, a program according to the present technology that is recorded in, for example, the ROM in advance and executing the program.

For example, a PLD such as an FPGA, or a device such as an ASIC may be used as the controller 11. Further, any computer such as a personal computer (PC) may serve as the controller 11.

In the present embodiment, a rotation controller 13 can be implemented as a functional block by the CPU executing a specified program, as illustrated in FIG. 2. Of course, dedicated hardware such as an integrated circuit (IC) may be used in order to implement the functional block.

The program is installed through, for example, various recording media. Alternatively, the installation of the program may be performed via, for example, the Internet.

The type and the like of a recording medium that records therein a program are not limited, and any computer-readable recording medium may be used. For example, any non-transitory computer-readable recording medium may be used.

Note that, typically, the controller 11 is situated inside of the image-capturing apparatus 100. Without being limited thereto, the controller 11 may be situated outside of the image-capturing apparatus 100, and may be connected to, for example, the inertial sensor 10 and the rotation drive section 12 to be capable of communicating with, for example, the inertial sensor 10 and the rotation drive section 12.

The rotation drive section 12 rotates the rotation section 1.

In the present embodiment, a motor 16 (refer to FIG. 5) is used as the rotation drive section 12.

The motor 16 is connected to the bottom 2b included in the rotation section 1 and situated opposite to the bottom 2a.

A specific configuration of the motor 16 is not limited. Further, a device other than the motor 16 may be used as the rotation drive section 12.

The rotation controller 13 controls rotation of the rotation section 1 on the basis of a result of detection performed by the inertial sensor 10.

For example, an operation performed to control the image-capturing direction of the camera module 21 is input by, for example, an operator (a user) of the image-capturing apparatus 100. The rotation controller 13 controls the image-capturing direction 7 of the camera module 21 in response to the operation being input by the operator.

Here, the rotation controller 13 controls a rotational motion of the rotation drive section 12 on the basis of a result of detection (a result of sensing) performed by the inertial sensor 10. This makes it possible to control rotation of the rotation section 1 with a high degree of accuracy, and thus to control the image-capturing direction 7 of the camera module 21 with a high degree of accuracy.

For example, the image-capturing apparatus 100 can be mounted on a mobile object such as a drone.

Information regarding a location and a pose of the image-capturing apparatus 100 (the camera module 21) can also be acquired on the basis of a result of detection performed by the inertial sensor 10, and this makes it possible to perform image-capturing with a high degree of accuracy using the image-capturing apparatus 100. This results in being able to capture a high-quality image.

Note that a specific algorithm used for rotation control performed by the rotation controller 13 is not limited.

### [Configuration of Image-Capturing Apparatus]

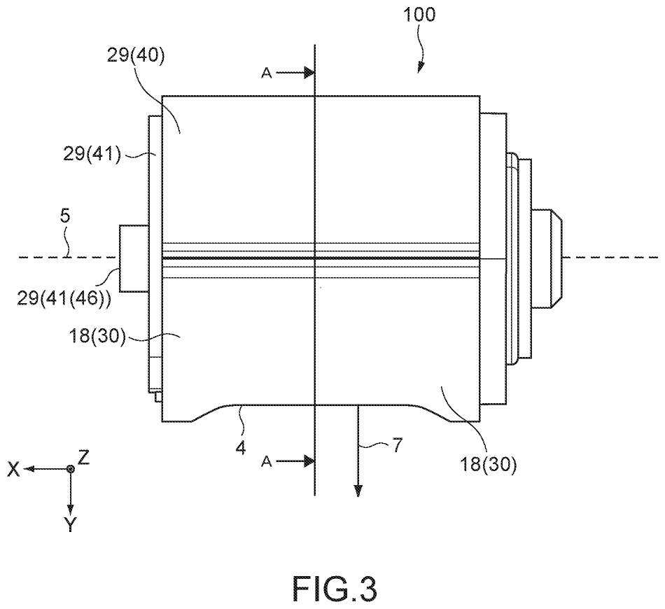

A specific example of a configuration of the image-capturing apparatus 100 is described with reference to FIGS. 3 to 7. First, each of the figures is described.

FIG. 3 is a side view of the image-capturing apparatus 100 as viewed from the positive direction on the Z direction.

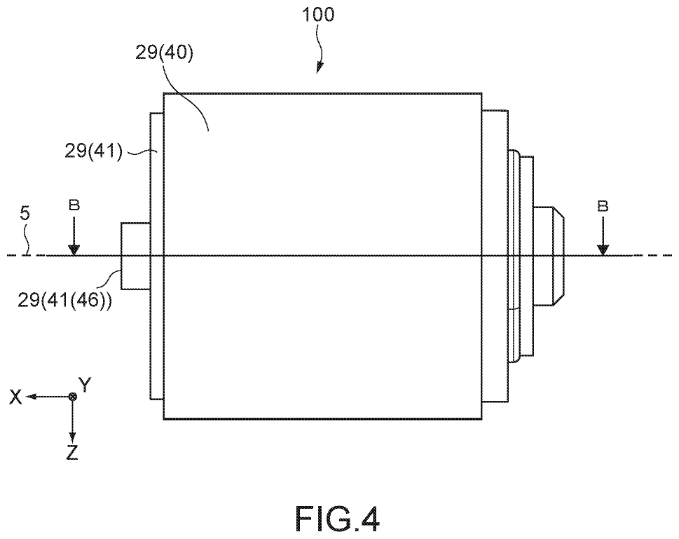

FIG. 4 is a side view of the image-capturing apparatus 100 as viewed from the negative direction on the Y direction.

FIG. 5 is a cross-sectional view along the line B-B illustrated in FIG. 4.

FIG. 6 is a perspective view illustrating an internal configuration of the image-capturing apparatus 100. FIG. 6 is a perspective view as viewed from an internal side of the front holder 18.

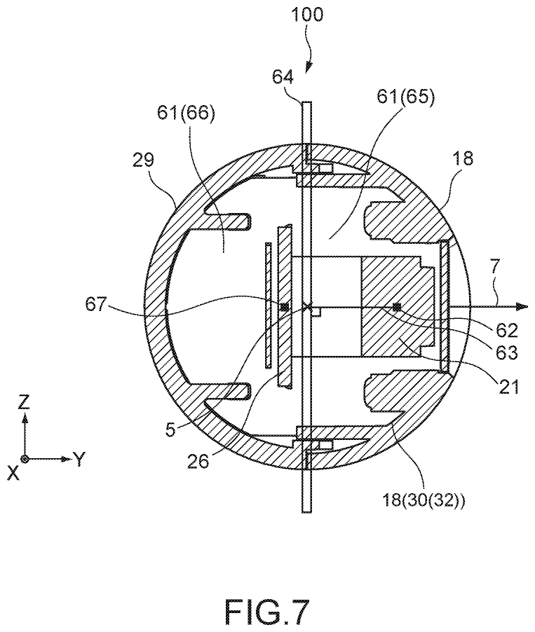

FIG. 7 is a cross-sectional view along the line A-A illustrated in FIG. 3.

As illustrated in FIGS. 5 and 6, the image-capturing apparatus 100 includes the window 4, the motor 16, a motor-use flexible substrate 17, the front holder 18, the camera module 21, a camera-use flexible substrate 22, an IMU substrate 26, a substrate-use screw 27, and a rear holder 29.

The front holder 18 can serve as the housing of the image-capturing apparatus 100.

The front holder 18 includes a semicylindrical portion 30 and a bottom 31. The semicylindrical portion 30 and the bottom 31 are made of, for example, a rigid material. This results in protecting various members included in the image-capturing apparatus 100 from an external impact.

Of course, a specific material and a specific shape of the front holder 18 are not limited.

In the present embodiment, the semicylindrical portion 30 has a shape that is nearly identical to a shape of one of two portions obtained by cutting a cylinder (that is, a hollow cylinder) into the two portions along a plane including a central axis of the cylinder.

In other words, the semicylindrical portion 30 has a shape of one of two portions obtained by cutting a cylinder into two halves, as illustrated in FIG. 6.

The semicylindrical portion 30 is arranged such that the central axis of the cylinder coincides with the rotational axis 5.

The semicylindrical portion 30 includes an inner surface 32 situated on a side of the rotational axis 5, and an outer surface 33 situated opposite to the inner surface 32. Further, the semicylindrical portion 30 includes two semi-annular arced surfaces 34 (34a and 34b) that face each other in the X direction.

As illustrated in FIG. 7, an internal space 61 is formed on a side of the inner surface 32 of the semicylindrical portion 30.

A mechanism used to hold various members, such as the camera module 21 and the IMU substrate 26, that are arranged in the internal space 61, is provided to the inner surface 32 of the semicylindrical portion 30.

The bottom 31 has a substantially discoid shape.

The bottom 31 is arranged such that half a circumferential portion of the bottom 31 is situated along the inner surface 32 of the semicylindrical portion 30 and is situated further inward than the arced surface 34b situated on a side of the negative direction on the X direction (that is, situated on a side of the positive direction on the X direction as viewed from the arced surface 34b).

The motor 16 is fixed to the bottom 31.

The motor 16 is fixed to the bottom 31 by, for example, fastening with a screw, bonding, or press fit. Further, the inside of the motor 16 may be directly attached to the front holder 18. Moreover, the method for fixing the motor 16 is not limited.

The rear holder 29 can serve as the housing of the image-capturing apparatus 100 together with the front holder 18.

The rear holder 29 includes a semicylindrical portion 40 and a bottom 41. The semicylindrical portion 40 and the bottom 41 are made of, for example, a rigid material. Of course, a specific material and a specific shape of the rear holder 29 are not limited.

The semicylindrical portion 40 of the rear holder 29 has a shape that is substantially identical to the shape of the semicylindrical portion 30 of the front holder 18. Further, the bottom 41 of the rear holder 29 also has a shape that is substantially identical to the shape of the bottom 31 of the front holder 18.

As in the case of the inner surface 32 of the semicylindrical portion 30 of the front holder 18, a mechanism used to hold various members included in the image-capturing apparatus 100 is provided to an inner surface 42 of the semicylindrical portion 40.

A cylinder-shaped columnar portion 46 is provided to the bottom 41. As illustrated in, for example, FIG. 3, the columnar portion 46 is configured to protrude from the bottom 41 in the positive direction on the X direction.

A circular opening is formed in a tip of the columnar portion 46.

The bottom 41 is configured such that half a circumferential portion of the bottom 41 is situated along the inner surface 42 of the semicylindrical portion 40.

Further, the bottom 41 is provided at a position that is substantially identical to a position of an end of the semicylindrical portion 40 (a portion of the semicylindrical portion 40 that is situated furthest forward in the positive direction on the X direction), as viewed from the Y direction.

In FIG. 3, a portion situated further downward than the rotational axis 5 corresponds to the semicylindrical portion 30 of the front holder 18. Further, a portion situated further upward than the rotational axis 5 corresponds to the semicylindrical portion 40 of the rear holder 29.

In the image-capturing apparatus 100, the front holder 18 is arranged at a position situated furthest forward in the positive direction on the Y direction. Further, the rear holder 29 is arranged at a position situated furthest forward in the negative direction on the Y direction.

Moreover, other members are arranged in the internal space 61 situated inside of the front holder 18 and the rear holder 29.

In other words, various members are held in the front holder 18 and the rear holder 29 by the front holder 18 and the rear holder 29 fitting to each other. This results in the image-capturing apparatus 100 being assembled, as illustrated in FIG. 1.

The side 3 illustrated in FIG. 1 is formed of the semicylindrical portion 30 of the front holder 18 and the semicylindrical portion 40 of the rear holder 29. Further, the bottom 2b is formed of the bottom 31 of the front holder 18, and the bottom 2a is formed of the bottom 41 of the rear holder 29. In other words, the entirety of the rotation section 1 illustrated in FIG. 1 is formed of the front holder 18 and the rear holder 29.

The front holder 18 and the rear holder 29 correspond to an embodiment of a rotation section according to the present technology.

The camera module 21 captures an image of the outside of the image-capturing apparatus 100.

Any camera may be used as the camera module 21. For example, a digital camera, an infrared camera, or the like with which a still image or a video can be captured. Alternatively, a camera, such as a time-of-flight (ToF) camera, a stereo camera, or a monocular camera, that includes a ranging function may be used.

The camera module 21 includes various mechanisms such as a lens system that are used to perform image-capturing.

The camera module 21 corresponds to an embodiment of an image-capturing section according to the present technology. A specific shape of the camera module 21 is not limited.

The camera module 21 is rotated integrally with the front holder 18 and the rear holder 29 in response to the front holder 18 and the rear holder 29 being rotated. Further, the image-capturing direction 7 of the camera module 21 is changed in response to the front holder 18 and the rear holder 29 being rotated.

The camera-use flexible substrate 22 is a substrate used to drive the camera module 21. In the present embodiment, the camera-use flexible substrate 22 is connected to the IMU substrate 26.

The camera-use flexible substrate 22 has a rectangular shape and can be bent. One of two ends of the camera-use flexible substrate 22 is connected to the camera module 21. Another of the two ends of the camera-use flexible substrate 22 is connected to the IMU substrate 26.

In the present embodiment, the camera-use flexible substrate 22 is bent to be folded in three in the Z direction, and the connections of the camera-use flexible substrate 22 are performed, as illustrated in FIG. 5. The bent camera-use flexible substrate 22 is generally U-shaped, as viewed from the Z direction.

In the present embodiment, the controller 11 controls a motion of the camera module 21. Supply of power, output of a control signal, and the like are performed through the camera-use flexible substrate 22.

Note that the method for connecting the camera module 21 and the IMU substrate 26 is not limited, and any method may be adopted. For example, the camera module 21 and the IMU substrate 26 may be connected to each other using, for example, a harness. The motor 16 rotates the front holder 18.

In the present embodiment, a power supply (not illustrated) is connected to the motor 16, and the motor 16 is driven by power supplied by the power supply. Of course, the method for driving the motor 16 is not limited, and any method may be adopted.

When the motor 16 is driven, the front holder 18 and the rear holder 29 are rotated integrally. Further, members, such as the IMU substrate 26, that are included in the image-capturing apparatus 100 are rotated integrally.

Further, in the present embodiment, the motor 16 is fixed outside of the image-capturing apparatus 100. Specifically, for example, the motor 16 is fixed to a mobile object on which the image-capturing apparatus 100 is mounted.

In this case, the image-capturing apparatus 100 is rotated relative to the mobile object.

Accordingly, the image-capturing apparatus 100 is rotated.

The motor-use flexible substrate 17 is a substrate used to drive the motor 16.

The motor-use flexible substrate 17 can be bent. As illustrated in FIG. 5, one of two ends of the motor-use flexible substrate 17 is connected to the motor 16. Further, another of the two ends of the motor-use flexible substrate 17 is connected to a surface of the IMU substrate 26 that is situated on a side of the negative direction on the Y direction (a surface of the IMU substrate 26 that does not face the camera module 21).

In the present embodiment, the rotation controller 13 of the controller 11 controls a motion of the motor 16. Supply of power, output of a control signal, and the like are performed through the motor-use flexible substrate 17.

Note that the method for connecting the motor 16 and the IMU substrate 26 is not limited, and any method may be adopted. For example, the motor 16 and the IMU substrate 26 may be connected to each other using, for example, a harness.

As illustrated in FIG. 6, an IMU sensor 60 is arranged on the IMU substrate 26.

The IMU substrate 26 is a substrate in the form of a substantially rectangular plate.

The IMU substrate 26 corresponds to an embodiment of a substrate according to the present technology.

As illustrated in FIG. 6, a convex portion 55 that protrudes in the negative direction on the X direction is provided to each of an upper-right corner and a lower-right corner of the IMU substrate 26. The convex portion 55 is provided to be inserted into the front holder 18.

Further, a through hole 56 is provided near an upper-left corner. The IMU substrate 26 is fastened to the front holder 18 with a screw through the through hole 56.

Specifically, a convex portion 57 is provided to the front holder 18 to extend toward the through hole 56 in the Y direction, as illustrated in FIG. 6. Further, a screw hole is provided to the convex portion 57.

As illustrated in FIG. 6, the substrate-use screw 27 passes through the through hole 56 to be fitted into the screw hole provided to the convex portion 57. This results in the IMU substrate 26 being fastened with a screw.

In the present embodiment, a screw that includes a screw head and a threaded portion is used as the substrate-use screw 27. Of course, a specific material and a specific shape of the substrate-use screw 27 are not limited.

Further, a through hole 58 is provided to a position, in the bottom 31 of the front holder 18, that corresponds to the convex portion 55 of the IMU substrate 26. In other words, two through holes 58 are provided to the bottom 31.

The convex portion 55 is inserted into the through hole 58. Further, an adhesive 59 is provided to a portion in which the insertion is performed. This results in the IMU substrate 26 being bonded to the front holder 18.

In the present embodiment, fastening with a screw is performed in one portion and bonding is performed in two portions, as described above. This results in the IMU substrate 26 being connected to the front holder 18.

As illustrated in FIG. 6, the IMU sensor 60 is arranged on the surface being included in the IMU substrate 26 and situated on the side of the negative direction on the Y direction (the surface being included in the IMU substrate 26 and situated opposite to the camera module 21).

The IMU sensor 60 corresponds to an embodiment of an inertial sensor according to the present technology. Further, the camera-use flexible substrate 22 and the motor-use flexible substrate 17 (not illustrated) are connected to the IMU substrate 26.

Moreover, a specific configuration of the IMU substrate 26 is not limited. For example, when the controller 11 is provided on the IMU substrate 26, hardware such as a CPU, a ROM, a RAM, and an HDD may be arranged on the IMU substrate 26.

### [Configurations of Arrangements of IMU Substrate and Camera Module]

Specific configurations of arrangements of the IMU substrate 26 and the camera module 21 are described.

In the present embodiment, the IMU substrate 26 is provided to the front holder 18 to be spaced from the camera module 21.

In FIG. 7, the camera module 21 is provided to the image-capturing apparatus 100 on a side of the positive direction on the Y direction. Further, the IMU substrate 26 is provided near the rotational axis 5 on the side of the negative direction on the Y direction as viewed from the rotational axis 5.

As described above, the IMU substrate 26 and the camera module 21 are spaced from each other to form a space between the IMU substrate 26 and the camera module 21.

Further, in the present embodiment, the IMU substrate 26 and the camera module 21 are situated across the rotational axis 5 from each other.

Specifically, the front holder 18 and the rear holder 29 have the internal space 61 in which the rotational axis 5 is arranged. The IMU substrate 26 is provided to the front holder 18 such that a center of gravity of the IMU substrate 26 is situated in a second division space when the internal space 61 is divided into a first division space and the second division space along a plane that includes the rotational axis 5 and is orthogonal to a perpendicular from a center of gravity of the camera module 21 to the rotational axis 5, the first division space being a space in which the center of gravity of the camera module 21 is situated, the second division space being a space in which the center of gravity of the camera module 21 is not situated.

Here, the internal space 61 is a space that is surrounded by the front holder 18 and the rear holder 29.

As illustrated in FIG. 7, the internal space 61 is formed as a substantially cylindrical space surrounded by the front holder 18 and the rear holder 29. The rotational axis 5 is arranged in the internal space 61.

A center of gravity 62 of the camera module 21 is a mass center of gravity (that is, a center of gravity based on density) of the camera module 21. In FIG. 7, the center of gravity 62 of the camera module 21 is indicated by a black square.

A perpendicular 63 from the center of gravity 62 of the camera module 21 to the rotational axis 5 is a straight line that is parallel to the Y axis and passes through the center of gravity 62 of the camera module 21.

In FIG. 7, the perpendicular 63 is indicated by a solid line.

A plane that is orthogonal to the perpendicular 63 and includes the rotational axis 5 is a plane that is orthogonal to the Y axis and includes the rotational axis 5 (that is parallel to the Z axis). Thus, the plane includes the rotational axis 5 and is parallel to an XZ-plane. This plane is hereinafter referred to as a division plane 64.

FIG. 7 schematically illustrates the division plane 64 using a vertically long rectangle.

Further, the division plane 64 divides the internal space 61 into two spaces.

In other words, the internal space 61 is divided into a space situated on a right side of the division plane 64, and a space situated on a left side of the division plane 64, as illustrated in FIG. 7.

The center of gravity of the camera module 21 is situated in the space on the right side. In other words, the space on the right side corresponds to a first division space 65 in which the center of gravity of the camera module 21 is situated.

Further, the center of gravity of the camera module 21 is not situated in the space on the left side. In other words, the space on the left side corresponds to a second division space 66 in which the center of gravity of the camera module 21 is not situated.

The IMU substrate 26 is provided to the front holder 18 such that the center of gravity of the IMU substrate 26 is situated in the second division space 66 when the internal space 61 is divided as described above.

Likewise, the center of gravity of the IMU substrate 26 is a mass center of gravity of the IMU substrate 26. In FIG. 7, a center of gravity 67 of the IMU substrate 26 is indicated by a black square.

As illustrated in FIG. 7, the center of gravity 67 of the IMU substrate 26 is situated in the second division space 66.

When the rotational axis 5 is situated in the internal space 61 formed by the front holder 18 and the rear holder 29 and when the internal space 61 is divided into two spaces by a plane that is parallel to the XZ-plane, as described above, the center of gravity of the IMU substrate 26 and the center of gravity of the camera module 21 are situated in the spaces different from each other (on sides opposite to each other).

For example, when a mass center of gravity and a positional center of gravity do not coincide with respect to each of the camera module 21 and the IMU substrate 26, a configuration of arrangement in which the mass centers of gravity of the camera module 21 and the IMU substrate 26 are situated in different spaces, whereas the positional centers of gravity of the camera module 21 and the IMU substrate 26 are situated in a single space, may be adopted.

Further, in the present embodiment, the camera module 21 is provided to be situated in the first division space 65. Furthermore, the IMU substrate 26 is provided to be situated in the second division space 66.

In other words, the camera module 21 is provided such that not only the center of gravity 62 of the camera module 21 but also the entirety of the camera module 21 is situated in the first division space 65. Further, the IMU substrate 26 is provided such that not only the center of gravity 67 of the IMU substrate 26 but also the entirety of the IMU substrate 26 is situated in the second division space 66.

As illustrated in FIG. 7, in the present embodiment, the entirety of the camera module 21 is situated in the first division space 65, and the entirety of the IMU substrate 26 is also situated in the second division space 66.

Of course, for example, a configuration of arrangement in which only the center of gravity of the camera module 21 is situated in the first division space 65 and all of the camera module 21 is not situated in the first division space 65, may be adopted.

For example, the center of gravity 62 is situated in the first division space 65 when only an end of the camera module 21 is situated in the second division space 66 and a large portion of the camera module 21 that is other than the end is situated in the first division space 65. Thus, such a configuration of arrangement can be adopted.

The same applies to the IMU substrate 26.

Further, in the present embodiment, the IMU substrate 26 is arranged to be oriented such that the IMU substrate 26 is orthogonal to the image-capturing direction 7 of the camera module 21.

In other words, the IMU substrate 26 is arranged to be oriented such that a substrate surface of the IMU substrate 26 is orthogonal to the image-capturing direction 7.

As illustrated in FIG. 7, the image-capturing direction 7 is parallel to the Y axis. Further, the surface of the IMU substrate 26 is arranged to be parallel to the XZ-plane. In other words, the image-capturing direction 7 and the surface of the IMU substrate 26 are orthogonal to each other.

Of course, the orientation of the arrangement of the IMU substrate 26 is not limited. For example, the IMU substrate 26 may be arranged such that the surface of the IMU substrate 26 is oblique (is not parallel) to the XZ-plane.

The IMU substrate 26 and camera module 21 are spaced from each other, as described above. This makes it possible to suppress transmission of heat of the camera module 21 to the IMU substrate 26. In other words, this makes it possible to improve the accuracy in measurement performed by the IMU sensor 60.

Further, in the present embodiment, the IMU substrate 26 and the camera module 21 are arranged in different spaces (the first division space 65 and the second division space 66).

This results in the center of gravity of the entirety of the image-capturing apparatus 100 being situated near the rotational axis 5.

Each of the IMU substrate 26 and the camera module 21 is a member having a certain mass. When they are arranged in a single space (for example, when the camera module 21 is arranged on the IMU substrate 26), there is a preponderance of mass on a side of the single space.

In other words, the center of gravity of the entirety of the image-capturing apparatus 100 is situated away from the rotational axis 5 (on a side of one of the spaces).

When the center of gravity of the entirety of the image-capturing apparatus 100 is situated away from the rotational axis 5, there is an increase in a torque necessary to rotate the image-capturing apparatus 100. In other words, there is an increase in necessary output performed by the motor 16. This results in burdens being imposed on the motor 16, and thus in increasing an amount of heat generated by the motor 16.

In the present embodiment, the center of gravity of the entirety of the image-capturing apparatus 100 is situated near the rotational axis 5. Thus, there is a decrease in a torque necessary for rotation, and thus heat generation by the motor 16 can be suppressed. This makes it possible to suppress transmission of heat to, for example, the IMU substrate 26.

Further, there is a decrease in necessary output performed by the motor 16. This makes it possible to make the entirety of the image-capturing apparatus 100 including the motor 16 smaller in size. Further, this makes it possible to reduce power consumption due to rotation.

Furthermore, the center of gravity is adjusted using arrangements of the IMU substrate 26 and the camera module 21. Thus, there is no need for other mechanisms used to adjust the center of gravity. This results in make the image-capturing apparatus 100 lighter in weight.

These effects are provided when the center of gravity of the IMU substrate 26 and the center of gravity of the camera module 21 are situated in different spaces. A greater effect can be provided when not only the centers of gravity but also the entirety of the IMU substrate 26 and the entirety of the camera module 21 are arranged in different spaces.

### [Structure for Holding Substrate]

An overview of a holding structure used to hold a substrate is described.

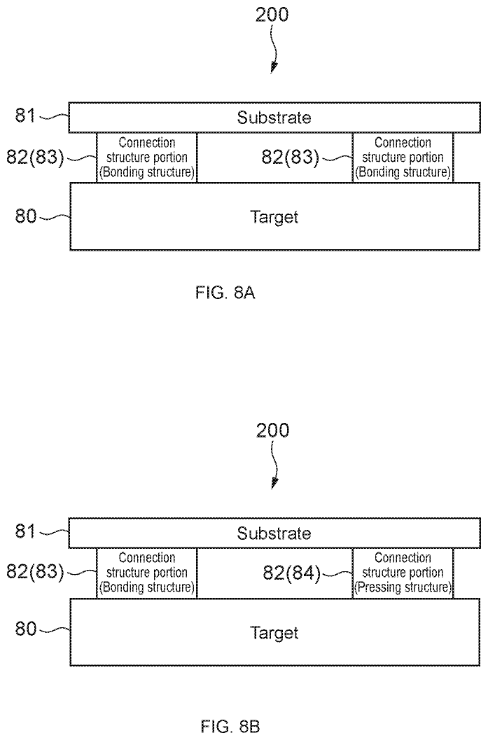

FIG. 8 schematically illustrates an overview of a holding structure 200 according to the present technology.

As illustrated in A and B of FIG. 8, the holding structure 200 is a structure used to provide a target 80 with a substrate 81 on which the inertial sensor 10 is arranged.

The holding structure 200 includes at least two connection structure portions 82 that are respectively provided to at least two portions of the substrate 81 and used to connect the substrate 81 to the target 80.

A and B of FIG. 8 each illustrate two connection structure portions 82 respectively provided to two portions of the substrate 81. However, at least three connection structure portions 82 may be respectively provided to at least three portions of the substrate 81.

Note that an illustration of the inertial sensor 10 arranged on the substrate 81 is omitted in FIGS. 8 to 15.

In the examples illustrated in A of FIG. 8, at least two connection structure portions 82 each have a bonding structure 83.

The bonding structure 83 is a structure obtained by an adhesive material being provided between the target 80 and substrate 81 being spaced from each other.

In the example illustrated in B of FIG. 8, one of at least two connection structure portions 82 has a pressing structure 84. Further, another of the at least two connection structure portions 82 has the bonding structure 83.

The pressing structure 84 is a structure obtained by the substrate 81 being pressed against the target 80 to be fixed to the target 80.

The connection structure portion 82 is not limited to the examples illustrated in A and B of FIG. 8, and, for example, any number that is at least two, such as three or four, may be adopted for the number of connection structure portions 82 provided. Further, all of the connection structure portions 82 may each have the bonding structure 83, or one of the connection structure portions 82 may have the pressing structure 84 and all of other of the connection structure portions 82 may each have the bonding structure 83.

The following are examples of combinations of the number of bonding structures 83 and the number of pressing structures 84, where the bonding structure 83 and the pressing structure 84 can be provided in the combinations.
(1) When there are two connection structure portions 82
Two bonding structures 83
One bonding structure 83 and one pressing structure 84
(2) When there are three connection structure portions 82
Three bonding structures 83
Two bonding structures 83 and one pressing structure 84
(3) When there are four connection structure portions 82
Four bonding structures 83
Three bonding structures 83 and one pressing structure 84

In other words, at least two connection structure portions 82 are provided, where at most one of the at least two connection structure portions 82 has the pressing structure 84 and all of others each have the bonding structure 83.

Note that, when portions of a plurality of portions are each provided with the bonding structure 83, the respective bonding structures 83 may have different structures and different shapes.

As described above, the substrate 81 is connected to the target 80 by the bonding structure 83 or the pressing structure 84.

In other words, the substrate 81 is provided on the target 80.

### [Holding Structure in Image-Capturing Apparatus]

The holding structure 200 illustrated in FIG. 8 is adopted in the image-capturing apparatus 100 according to the present embodiment, with the front holder 18 (the rotation section 1) being the target 80. In other words, the holding structure 200 is configured such that the IMU substrate 26 is provided to the front holder 18 (the rotation section 1) to be rotated integrally with the front holder 18 (the rotation section 1).

In the present embodiment, the IMU substrate 26 is fastened to the convex portion 57 of the front holder 18 with a screw, as illustrated in FIG. 6.

Accordingly, the pressing structure 84 obtained by the IMU substrate 26 being pressed against the front holder 18 to be fixed to the front holder 18 is provided.

In the present embodiment, a structure obtained by the IMU substrate 26 being fixed to the front holder 18 through the substrate-use screw 27 (a fastening member) is adopted as the pressing structure 84.

Further, in the present embodiment, the convex portion 55 of the IMU substrate 26 is inserted into each of two through holes 58 provided to the bottom 31 of the front holder 18, and the convex portion 55 is bonded to the through hole 58 using the adhesive 59.

Accordingly, the bonding structure 83 obtained by an adhesive material being provided between the front holder 18 and IMU substrate 26 being spaced from each other is provided.

In the present embodiment, a structure obtained by an adhesive material being provided on the basis of a position of the through hole 58 in a state in which the convex portion 55 (an insertion portion) of the IMU substrate 26 is inserted into the through hole 58 of the front holder 18, is adopted as the bonding structure 83.

In other words, in the present embodiment, the holding structure 200 includes three connection structure portions 82 respectively provided to three portions of the IMU substrate 26.

Further, one of the three connection structure portions 82 has the pressing structure 84. The others, that is, two of the three connection structure portions 82 each have the bonding structure 83.

Further, a portion such as the convex portion 57 and the bottom 31 to which the IMU substrate 26 is connected may be referred to as a holder.

In the image-capturing apparatus 100, one portion of the IMU substrate 26 is fastened with a screw, and two portions of the IMU substrate 26 are bonded. Accordingly, the IMU substrate 26 is connected to the front holder 18.

Thus, three connection structure portions 82 are provided.

Of course, for example, an order of fastening of the IMU substrate 26 with a screw and bonding of the IMU substrate 26 is not limited. For example, bonding may be performed after fastening with a screw is performed. Further, a portion to be fastened with a screw is tentatively fixed and bonding is performed. Thereafter, the tentatively fixed portion is fastened with a screw. Such a method may be adopted. Moreover, fastening with a screw and bonding may be performed by any method.

A portion where the through hole 58 provided to the bottom 31 and the convex portion 55 of the IMU substrate 26 are bonded corresponds to an embodiment of a bonding structure according to the present technology. In other words, two bonding structures 83 are provided to the image-capturing apparatus 100.

In the present embodiment, the convex portion 55 is inserted into the through hole 58 with a space. In other words, the convex portion 55 is inserted into the through hole 58 such that the convex portion 55 is situated in a space formed in the through hole 58 (within a hole) but is not brought into contact with a surface of the bottom 31 in which the through hole 58 is formed.

The adhesive 59 is provided in and near a gap formed between the convex portion 55 and the through hole 58. In other words, the convex portion 55 and through hole 58 being situated with a space are bonded through the adhesive 59 acting as a bridge.

The adhesive 59 corresponds to an embodiment of an adhesive material according to the present technology.

Of course, the bonding structure 83 is not limited thereto.

A portion where the IMU substrate 26 is fastened to the convex portion 57 of the front holder 18 with a screw corresponds to an embodiment of a pressing structure according to the present technology. In other words, one pressing structure 84 is provided to the image-capturing apparatus 100.

In the present embodiment, the pressing structure 84 is a structure obtained by the IMU substrate 26 being fixed to the front holder 18 through the substrate-use screw 27.

Specifically, the through hole 56 is provided to the IMU substrate 26, and the threaded portion of the substrate-use screw 27 passes through the through hole 56. Further, the screw hole provided to the convex portion 57 extends, and the threaded portion is fitted into the screw hole. Accordingly, the IMU substrate 26 is fastened with a screw.

The substrate-use screw 27 corresponds to an embodiment of a fastening member according to the present technology and corresponds to an embodiment of a screw according to the present technology.

The IMU substrate 26 fastened with a screw is situated between the screw head of the substrate-use screw 27 and the convex portion 57 of the front holder 18.

In other words, the screw head of the substrate-use screw 27 presses the IMU substrate 26 against the front holder 18 to fix the IMU substrate 26 to the front holder 18.

Of course, the pressing structure 84 is not limited thereto. In other words, a pressing-and-fixation method other than the method using a screw may be adopted.

The substrate 81 is connected through at least two connection structure portions 82, where one of the at least two connection structure portions 82 has the pressing structure 84 and another of the at least two connection structure portions 82 has the bonding structure 83. This makes it possible to improve the accuracy in measurement performed by the IMU sensor 60 arranged on the IMU substrate 26.

Specifically, first, the pressing structure 84 makes it possible to stably fix the IMU substrate 26. For example, in the image-capturing apparatus 100, the IMU substrate 26 is situated between the screw head of the substrate-use screw 27 and the convex portion 57 of the front holder 18, and further, the threaded portion of the substrate-use screw 27 is fitted into the screw hole. This results in preventing weaker holding of the IMU substrate 26 even if vibration is continuously applied to the IMU substrate 26. In other words, the IMU substrate 26 is fixed stably.

Further, the bonding structure 83 makes it possible to fix the IMU substrate 26 without applying stress to the IMU substrate 26.

Due to, for example, design errors, there is a variation in the height of fixation portions (reception surfaces) to which a substrate is fixed by being fastened with a screw. When the IMU substrate 26 is connected closely to reception surfaces of a plurality of reception surfaces having different heights (without being spaced from the reception surfaces of the plurality of reception surfaces), the IMU substrate 26 is brought into contact with the reception surfaces, and the IMU substrate 26 tries to follow the reception surfaces. This results in exerting force that deforms the IMU substrate 26.

Further, when the IMU substrate 26 is slightly warped in a state in which, for example, there is a relative shift between the IMU substrate 26 and the fixation portion, the force deforming the IMU substrate 26 is also exerted.

This results in deforming the IMU substrate 26, and in a position and an angle of the IMU sensor 60 on the substrate being shifted. In other words, there is a reduction in the accuracy in measurement performed by the IMU sensor 60.

In the present embodiment, with respect to a portion of bonding performed using the bonding structure 83, the IMU substrate 26 and the front holder 18 are spaced from each other, and the adhesive 59 is provided between the IMU substrate 26 and the front holder 18. Thus, force is not exerted by the reception surface, and thus force that is exerted due to the variation in height and deforms the IMU substrate 26 is not exerted.

When vibration is caused due to movement of the image-capturing apparatus 100 or a mobile object in a state in which the IMU substrate 26 is fixed by only one portion of the IMU substrate 26 being fastened with a screw (the pressing structure 84), the IMU sensor 60 is greatly affected by the vibration. In other words, the IMU sensor 60 provided on the IMU substrate 26 also vibrates. This results in a reduction in the accuracy in measurement performed by the IMU sensor 60.

In the present embodiment, the IMU substrate 26 is fixed by one pressing structure 84 and at least one bonding structure 83. In other words, a plurality of portions of the IMU substrate 26 is fixed. This makes it possible to suppress an impact that vibration has on the IMU substrate 26. This results in there being no reduction in the accuracy in measurement performed by the IMU sensor 60.

As described above, the configuration in which one of structures is the pressing structure 84 and all of other of the structures are the bonding structures 83 makes it possible to fix the IMU substrate 26 stably while suppressing force that deforms the IMU substrate 26. Further, this makes it possible to suppress an impact that vibration has on the IMU substrate 26.

This makes it possible to improve the accuracy in measurement performed by the IMU sensor 60.

Further, the fixation method for performing fixation using all of the connection structure portions 82 each having the bonding structure 83 also makes it possible to improve the accuracy in measurement performed by the IMU sensor 60.

Specifically, the bonding structures 83 fix the IMU substrate 26 while suppressing stress applied to the IMU substrate 26. Thus, the force deforming a substrate is not exerted.

Further, at least two portions of the IMU substrate 26 are fixed. This suppresses an impact of vibration.

This makes it possible to improve the accuracy in measurement performed by the IMU sensor 60.

### [Variations of Bonding Structure]

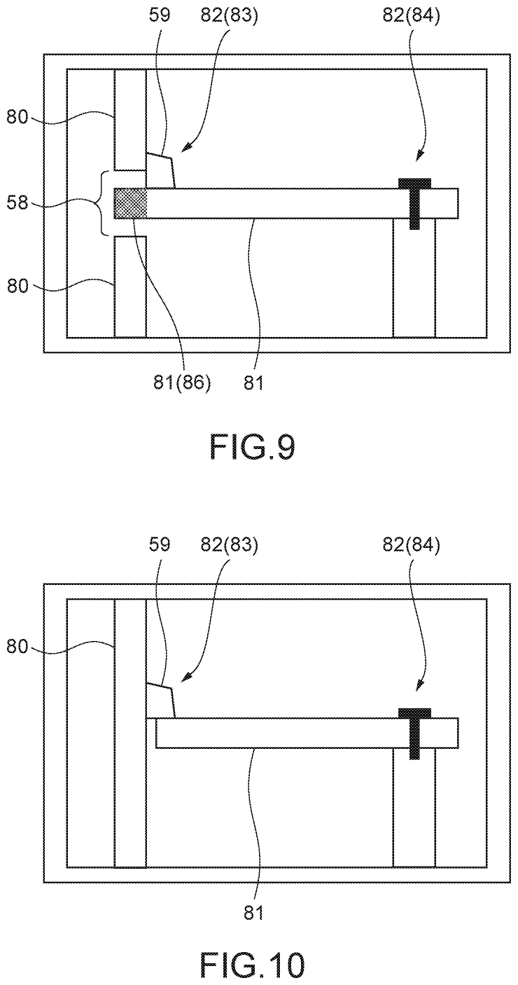

FIGS. 9 to 13 schematically illustrate variations of the bonding structure 83.

Note that FIGS. 9 to 13 each illustrate, on the right, a portion of connection performed by fastening with a screw as an example of the pressing structure 84.

The bonding structure 83 includes a structure obtained by the adhesive 59 being provided on the basis of a position of a hole of the target 80 in a state in which an insertion portion of the substrate 81 is inserted into the hole.

In the example illustrated in FIG. 9, a portion of the substrate 81 is inserted into the through hole 58 of the target 80. In other words, the through hole 58 corresponds to an embodiment of a hole of a target according to the present technology. Of course, a shape of the hole of the target 80 is not limited. For example, a concave portion may be provided as the hole instead of the through hole, and a portion of the substrate 81 may be inserted into the provided concave portion.

Further, a portion of the substrate 81 that is inserted into the through hole 58 corresponds to an embodiment of an insertion portion of a substrate according to the present technology. In FIG. 9, an insertion portion 86 is indicated by a dot pattern.

In the image-capturing apparatus 100, the convex portion 55 provided to the IMU substrate 26 corresponds to an embodiment of the insertion portion of the substrate according to the present technology.

The adhesive 59 is provided on the basis of the position of the hole.

In the example illustrated in FIG. 9, the adhesive 59 is provided to cover at least a portion of an opening of the through hole 58.

Specifically, the bonding material 59 is provided between the target 80 and the substrate 81 to cover a portion of a right opening of the through hole 58.

Typically, the bonding material 59 is provided to cover at least a portion of an opening included in the through hole 58 and situated on a side from which the convex portion 55 is inserted.

Of course, without being limited thereto, the bonding material 59 may be provided to cover the entirety of two openings of the through hole 58.

In the example illustrated in FIG. 10, the target 80 includes a flat surface, and the substrate 81 is arranged near the surface. The substrate 81 is spaced from the target 80 such that a surface of the substrate 81 is vertical to the flat surface of the target 80.

As illustrated in FIG. 10, the adhesive 59 is provided to a portion that is included in an upper surface of the substrate 81 and situated near the target 80.

Accordingly, the substrate 81 is bonded to the surface of the target 80.

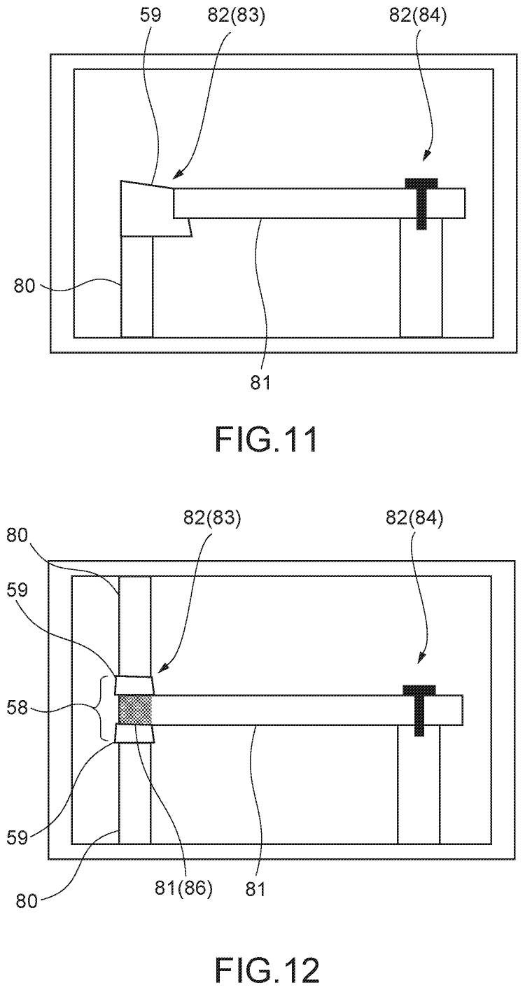

In the example illustrated in FIG. 11, the target 80 and the substrate 81 are spaced from each other, and the adhesive 59 is provided between a side of the target 80 and a side of the substrate 81.

The side of the target 80 and the side of the substrate 81 may be bonded through the adhesive 59 acting as a bridge.

In the example illustrated in FIG. 12, the through hole 58 is filled with the adhesive 59.

In FIG. 12, the adhesive 59 is filled into all of the space formed in the through hole 58 except for a region, in the space, that is occupied by the insertion portion 86. In other words, spaces situated above and below the insertion portion 86 are completely filled with the adhesive 59.

Of course, the space formed in the through hole 58 may be partially filled with the adhesive 59.

The method for providing the adhesive 59 covering at least a portion of an opening of the through hole 58, as illustrated in, for example, FIG. 9, and the method for filling the through hole 58 with the adhesive 59, as illustrated in FIG. 12 may be performed at the same time.

In other words, a configuration in which the adhesive 59 filled into the through hole 58 overflows into the outside of the through hole 58 to cover the opening of the through hole 58, may be adopted.

Of course, a shape of a hole of the substrate 81 is not limited. For example, a concave portion may be provided as the hole.

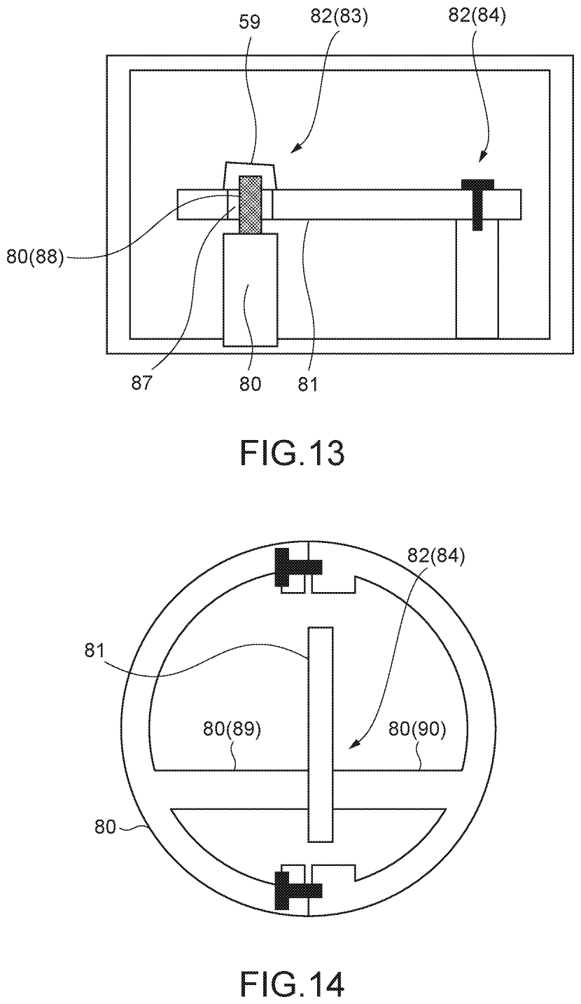

A structure obtained by an adhesive material being provided on the basis of a position of a hole of the substrate 81 in a state in which an insertion portion of the target 80 is inserted into the hole, as illustrated in FIG. 13, may be adopted as a bonding structure.

FIG. 13 illustrates the target 80 on the left. The target 80 includes an insertion portion 88 at an upwardly oriented tip portion. In FIG. 13, the insertion portion 88 is indicated by a dot pattern.

The insertion portion 88 corresponds to an embodiment of an insertion portion of a target according to the present technology.

For example, a boss that is provided to the target 80 serves as the insertion portion 88. Of course, a specific shape and the like of the insertion portion 88 are not limited.

The adhesive 59 is provided on the basis of the position of the hole.

As illustrated in FIG. 13, the insertion portion 88 is inserted into the through hole 87 to protrude upwardly from the through hole 87. Further, the adhesive 59 is provided to cover an upper opening of the through hole 87.

The adhesive 59 is provided to be in contact with an upper portion of the insertion portion 88 and with a surface that is included in an upper portion of the substrate 81 and situated near the through hole 87. This results in the substrate 81 and the target 80 being bonded to each other.

As described above, various variations of the bonding structure 83 as illustrated in FIGS. 9 to 13 can be adopted according to configurations of, for example, the target 80 and the substrate 81.

For example, when the provision of a through hole to the IMU substrate 26 in the image-capturing apparatus 100 is advantageous in terms of design, bonding can be performed effectively by, for example, adopting the bonding structure 83 illustrated in FIG. 13.

In particular, the through hole 87 may serve as a positioning hole of the substrate 81 in the example of FIG. 13. In this case, a position of the substrate 81 relative to the target 80 can be determined accurately.

Moreover, a specific structure of the bonding structure 83 is not limited, and any structure may be adopted. For example, bonding in a wide range, such as bonding of all of the sides of the substrate 81, may be performed.

### [Variations of Pressing Structure]

In the image-capturing apparatus 100, the IMU substrate 26 is fixed by being fastened with a screw. However, the pressing structure 84 is not limited to such a structure.

Variations of the pressing structure 84 are described below.

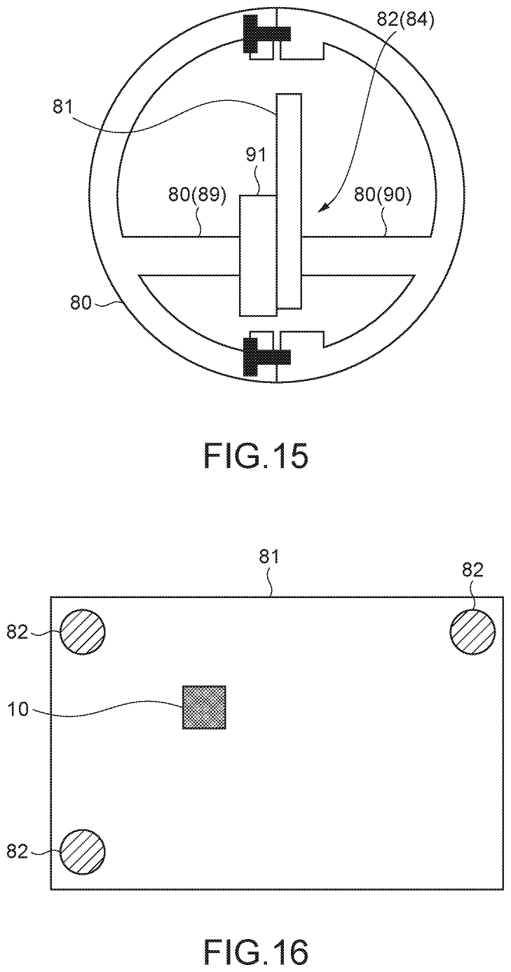

FIGS. 14 and 15 schematically illustrate examples of the pressing structure 84.

FIGS. 14 and 15 illustrate different examples of the pressing structure 84.

Note that the target 80 and the substrate 81 are bonded to each other using the bonding structure 83 in a portion that is not illustrated in each of FIGS. 14 and 15.

In the example illustrated in FIG. 14, the pressing structure 84 is a structure obtained by the substrate 81 being sandwiched using the target 80 to be fixed to the target 80.

As illustrated in FIG. 14, the target 80 includes a first fixation portion 89 that protrudes toward the right. Further, the target 80 includes a second fixation portion 90 that protrudes toward the left.

The substrate 81 is sandwiched between the first fixation portion 89 and the second fixation portion 90. In other words, the substrate 81 is sandwiched such that the first fixation portion 89 is brought into contact with a left surface of the substrate 81 and the second fixation portion 90 is brought into contact with a right surface of the substrate 81, and the substrate 81 is pressed by the first fixation portion 89 and the second fixation portion 90 to be fixed.

When the pressing structure 84 described above is provided to the image-capturing apparatus 100, for example, a convex portion is provided to each of the front holder 18 and the rear holder 29, and the IMU substrate 26 is sandwiched between the convex portions to be fixed. In this case, the front holder 18 and the rear holder 29 correspond to the target 80. Further, for example, the convex portion of the front holder 18 corresponds to the first fixation portion 89, and the convex portion of the rear holder 29 corresponds to the second fixation portion 90.

Of course, specific shapes of the first fixation portion 89 and the second fixation portion 90 are not limited when the first fixation portion 89 and the second fixation portion 90 are provided. Further, the method for sandwiching and fixation using the target 80 is also not limited, and any method may be adopted.

Further, at least one of the first fixation portion 89 or the second fixation portion 90 may fix the substrate 81 through an elastic body.

In the example illustrated in FIG. 15, a plate elastic body 91 is situated between the first fixation portion 89 and the substrate 81. Thus, the substrate 81 is put between the first fixation portion 89 and the second fixation portion 90 such that the left surface of the substrate 81 is brought into contact with a right surface of the elastic body 91 and such that the right surface of the substrate 81 is brought into contact with the second fixation portion 90, and the substrate 81 is pressed to be fixed.

In this example, the elastic body 91 is used only by the first fixation portion 89 to fix the substrate 81. Of course, the elastic body 91 may be situated only between the second fixation portion 90 and the substrate 81. Further, the elastic bodies 91 may be respectively situated between the first fixation portion 89 and the substrate 81 and between the second fixation portion 90 and the substrate 81.

Any elastic member such as rubber or a spring may be used as the elastic body 91.

Further, the method for fixing the substrate 81 through the elastic body 91 is not limited. For example, the substrate 81 may be fixed by a method other than the method in which the elastic body 91 is situated between the substrate 81 and the fixation portion.

The pressing structure 84 obtained by the substrate 81 being sandwiched using the target 80 to be fixed to the target 80 makes it possible to fix the substrate 81 stably.

Specifically, the substrate 81 is strongly held down by force applied through the first fixation portion 89 and the second fixation portion 90. Thus, the substrate 81 is less likely to be shifted from a position at which the substrate 81 is to be fixed or to come out of the fixation position when force acts on the substrate 81 from the outside.

Further, when the substrate 81 is fixed through the elastic body 91, pressing and fixation with a desired force can be performed by adjusting elasticity of the elastic body 91 as appropriate. For example, the use of the elastic body 91 having a high elasticity makes it possible to stably fix the substrate 81 with a strong force.

### [Configuration of Arrangement of Connection Structure Portion]

In the present embodiment, positions of at least two connection structure portions 82 are set on the basis of a position of the inertial sensor 10 on the substrate 81.

Variations of a configuration of arrangement of the connection structure portion 82 are described below.

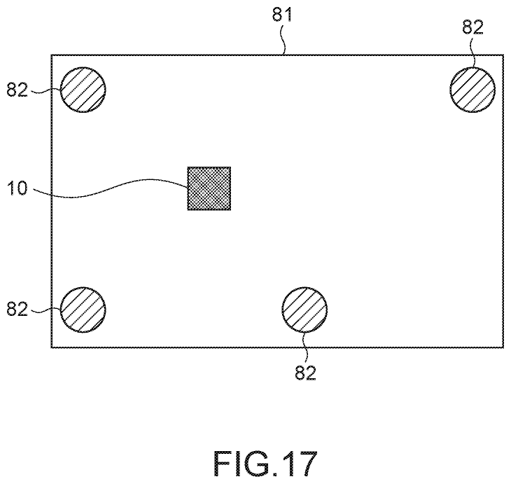

FIGS. 16 and 17 schematically illustrate examples of the configuration of the arrangement of the connection structure portion 82.

In the example illustrated in FIG. 16, the connection structure portion 82 is provided to each of three portions that are an upper-left corner, a lower-left corner, and an upper-right corner of the substrate 81.

Further, the inertial sensor 10 is arranged to be surrounded by the connection structure portions 82 respectively provided to the three portions.

In the image-capturing apparatus 100, the inertial sensor 10 is also arranged to be surrounded by the connection structure portions 82 respectively provided to the three portions. Specifically, the bonding structure 83 is provided to each of two portions that are a corner of the IMU substrate 26 that is situated on the side of the negative direction on the X direction and on a side of the positive direction on the Z direction in FIG. 6, and a corner of the IMU substrate 26 that is situated on the side of the negative direction on the X direction and on a side of the negative direction on the Z direction in FIG. 6. Further, the pressing structure 84 is provided at a corner of the IMU substrate 26 that is situated on a side of the positive direction on the X direction and on the side of the positive direction on the Z direction in FIG. 6. The IMU sensor 60 is arranged near a center portion of the IMU substrate 26 to be surrounded by the connection structure portions 82 respectively provided to the three portions.

In the example illustrated in FIG. 17, the connection structure portion 82 is provided to each of four portions that are the upper-left corner of the substrate 81, the lower-left corner of the substrate 81, the upper-right corner of the substrate 81, and a portion situated around a middle portion of a side of the substrate 81.

In this example, the inertial sensor 10 is also arranged to be surrounded by the connection structure portions 82 respectively provided to the four portions.

As described above, the inertial sensor 10 is arranged to be surrounded by, for example, at least two connection structure portions 82. In other words, the position of the inertial sensor 10 is set on the basis of respective positions of at least two connection structure portions 82.

In other words, on the basis of the position of the inertial sensor 10, the respective positions of at least two connection structure portions 82 are set to surround the inertial sensor 10.

The method for setting the respective positions of at least two connection structure portions 82 on the basis of the position of the inertial sensor 10 is not limited.

For example, the connection structure portion 82 may be provided at a portion other than a corner of the substrate 81.

Further, when, for example, the connection structure portions 82 are respectively provided at two portions, the connection structure portions 82 may be arranged such that the inertial sensor 10 is situated between the connection structure portions 82.

Moreover, the positions may be set by any method.

Further, a combination of the bonding structure 83 and pressing structure 84 corresponding to the connection structure portions 82 is not limited.

Furthermore, in this example, the inertial sensor 10 is arranged at a center of gravity obtained using respective positions of at least two connection structure portions 82.

In FIG. 16, the inertial sensor 10 is arranged at a positional center of gravity of a triangle formed by three connection structure portions 82.

Further, in FIG. 17, the inertial sensor 10 is arranged at a positional center of gravity of a quadrilateral formed by four connection structure portions 82.

Moreover, when, for example, the connection structure portions 82 are respectively provided to two portions, a positional center of gravity is a middle point of a line connecting the two connection structure portions 82. Thus, the inertial sensor 10 is arranged at the middle point.

The above-described setting of the position of the connection structure portion 82 results in stably arranging the inertial sensor 10 on the substrate 81.

When, for example, the connection structure portion 82 is provided to each of three portions that are the upper-left corner, the lower-left corner, and the upper-right corner, as illustrated in FIG. 16, a lower-right corner is not fixed to the target 80. Thus, when the substrate 81 vibrates, the lower-right corner is greatly affected by the vibration.

In other words, when, for example, the inertial sensor 10 is arranged at the lower-right corner, the inertial sensor 10 vibrates. This results in a reduction in sensing accuracy.

On the other hand, a portion, on the substrate 81, that is surrounded by the connection structure portions 82 is less likely to be affected by vibration. In the present embodiment, the inertial sensor 10 is arranged in the portion surrounded by the connection structure portions 82. This makes it possible to suppress an impact that vibration has on the inertial sensor 10.

This makes it possible to improve the accuracy in measurement performed by the inertial sensor 10.

Further, a positional center of gravity that is situated in the portion surrounded by the connection structure portions 82 and obtained using respective positions of the connection structure portions 82 is a portion that is particularly less likely to be affected by vibration.

In the present embodiment, the inertial sensor 10 is arranged at a positional center of gravity. This makes it possible to greatly suppress an impact that vibration has on the inertial sensor 10.

This makes it possible to improve the accuracy in measurement performed by the inertial sensor 10.

Note that when the substrate 81 is small in size, the substrate 81 is less likely to be affected by vibration. In such a case, the inertial sensor 10 is not greatly affected by vibration even when the inertial sensor 10 is arranged without being surrounded by the connection structure portions 82.

Thus, for example, an arrangement configuration in which the connection structure portion 82 is provided to each of two portions that are the upper-left corner and the upper-right corner of the substrate 81, and the inertial sensor 10 is arranged in a center portion of the substrate 81, may be adopted.

In the holding structure 200 according to the present embodiment, at least two connection structure portions 82 used to connect the substrate 81 to the target 80 are respectively provided to at least two portions of the substrate 81, as described above. The at least two connection structure portions 82 each have the bonding structure 83 obtained by the bonding material 59 being provided between the target 80 and substrate 81 being spaced from each other. Alternatively, one of the at least two connection structure portions 82 has the pressing structure 84 obtained by the substrate 81 being pressed against the target 80 to be fixed to the target 80, and another of the at least two connection structure portions 82 has the bonding structure 83. This makes it possible to improve the accuracy in measurement performed by the inertial sensor 10.

Further, the configuration in which one of structures is the pressing structure 84 and all of other of the structures are the bonding structures 83 makes it possible to fix the substrate 81 stably while suppressing force that deforms the substrate 81. Further, this makes it possible to suppress an impact that vibration has on the substrate 81.

This makes it possible to improve the accuracy in measurement performed by the inertial sensor 10.

Further, the configuration in which all of the connection structure portions 82 each have the bonding structure 83 makes it possible to fix the substrate 81 while suppressing stress applied to the substrate 81. Furthermore, at least two portions of the substrate 81 are fixed. This suppresses an impact of vibration.

This makes it possible to improve the accuracy in measurement performed by the inertial sensor 10.

The respective configurations of the image-capturing apparatus, the holding structure, and the like described with reference to the respective figures are merely embodiments, and any modifications may be made thereto without departing from the spirit of the present technology. In other words, for example, any other configurations and the like for purpose of practicing the present technology may be adopted.

When wording such as “substantially” is used in the present disclosure, such wording is merely used to facilitate the understanding of the description, and whether the wording such as “substantially” is used has no particular significance.

In other words, in the present disclosure, expressions, such as “center”, “middle”, “uniform”, “equal”, “similar”, “orthogonal”, “parallel”, “symmetric”, “extend”, “axial direction”, “columnar”, “cylindrical”, “ring-shaped”, “annular”, “rectangular”, and “discoid” that define, for example, a shape, a size, a positional relationship, and a state respectively include, in concept, expressions such as “substantially the center/substantial center”, “substantially the middle/substantially middle”, “substantially uniform”, “substantially equal”, “substantially similar”, “substantially orthogonal”, “substantially parallel”, “substantially symmetric”, “substantially extend”, “substantially axial direction”, “substantially columnar”, “substantially cylindrical”, “substantially ring-shaped”, “substantially annular”, “substantially rectangular”, and “substantially discoid”.

For example, the expressions such as “center”, “middle”, “uniform”, “equal”, “similar”, “orthogonal”, “parallel”, “symmetric”, “extend”, “axial direction”, “columnar”, “cylindrical”, “ring-shaped”, “annular”, “rectangular”, and “discoid” also respectively include states within specified ranges (such as a range of +/−10%), with expressions such as “exactly the center/exact center”, “exactly the middle/exactly middle”, “exactly uniform”, “exactly equal”, “exactly similar”, “completely orthogonal”, “completely parallel”, “completely symmetric”, “completely extend”, “fully axial direction”, “perfectly columnar”, “perfectly cylindrical”, “perfectly ring-shaped”, “perfectly annular”, “perfectly rectangular”, and “perfectly discoid” being respectively used as references.

Thus, an expression that does not include the wording such as “substantially” can also include, in concept, a possible expression including the wording such as “substantially”. Conversely, a state expressed using the expression including the wording such as “substantially” may include a state of “exactly/exact”, “completely”, “fully”, or “perfectly”.

In the present disclosure, an expression using “-er than” such as “being larger than A” and “being smaller than A” comprehensively includes, in concept, an expression that includes “being equal to A” and an expression that does not include “being equal to A”. For example, “being larger than A” is not limited to the expression that does not include “being equal to A”, and also includes “being equal to or greater than A”. Further, “being smaller than A” is not limited to “being less than A”, and also includes “being equal to or less than A”.

When the present technology is carried out, it is sufficient if a specific setting or the like is adopted as appropriate from expressions included in “being larger than A” and expressions included in “being smaller than A”, in order to provide the effects described above.

At least two of the features of the present technology described above can also be combined. In other words, the various features described in the respective embodiments may be combined discretionarily regardless of the embodiments. Further, the various effects described above are not limitative but are merely illustrative, and other effects may be provided.

Note that the present technology may also take the following configurations.

(1) A holding structure used to provide, to a target, a substrate on which an inertial sensor is arranged, the holding structure including
at least two connection structure portions that are respectively provided to at least two portions of the substrate, the at least two connection structure portions being used to connect the substrate to the target, in which
the at least two connection structure portions each have a bonding structure obtained by an adhesive material being provided between the target and substrate being spaced from each other, or
one of the at least two connection structure portions has a pressing structure obtained by the substrate being pressed against the target to be fixed to the target, and another of the at least two connection structure portions has the bonding structure.
   (2) The holding structure according to (1), in which
the pressing structure includes a structure obtained by the substrate being fixed to the target through a fastening member.
   (3) The holding structure according to (2), in which
the fastening member is a screw.
   (4) The holding structure according to (1), in which
the pressing structure includes a structure obtained by the substrate being sandwiched using the target to be fixed to the target.
   (5) The holding structure according to (4), in which
the target includes a first fixation portion and a second fixation portion between which the substrate is sandwiched to be fixed to the target, and
at least one of the first fixation portion or the second fixation portion fixes the substrate to the target through an elastic body.
   (6) The holding structure according to any one of (1) to (5), in which
the bonding structure includes a structure obtained by the adhesive material being provided on the basis of a position of a hole of the target in a state in which an insertion portion of the substrate is inserted into the hole.
   (7) The holding structure according to (6), in which
the hole is a through hole.
   (8) The holding structure according to (6) or (7), in which
the adhesive material is provided to cover at least a portion of an opening of the hole.
   (9) The holding structure according to any one of (6) to (8), in which
the hole is filled with the adhesive material.
   (10) The holding structure according to any one of (1) to (9), in which
the bonding structure includes a structure obtained by the adhesive material being provided on the basis of a position of a hole of the substrate in a state in which an insertion portion of the target is inserted into the hole.
   (11) The holding structure according to any one of (1) and (6) to (10), in which
the at least two connection structure portions each have the bonding structure.
   (12) The holding structure according to any one of (1) to (11), in which
one of the at least two connection structure portions has the pressing structure, and
another of the at least two connection structure portions has the bonding structure.
   (13) The holding structure according to any one of (1) to (12), in which
the inertial sensor is configured to include at least one of an acceleration sensor or an angular velocity sensor.
   (14) The holding structure according to any one of (1) to (13), in which
respective positions of the at least two connection structure portions are set on the basis of a position of the inertial sensor on the substrate.
   (15) The holding structure according to any one of (1) to (14), in which
a position of the inertial sensor is set on the basis of respective positions of the at least two connection structure portions.
   (16) The holding structure according to (15), in which
the inertial sensor is arranged at a center of gravity obtained by using the respective positions of the at least two connection structure portions.
   (17) The holding structure according to any one of (1) to (16), in which
the holding structure is configured such that the substrate is provided to a rotation section to be rotated integrally with the rotation section, the rotation section being the target, the rotation section being rotatable about a specified rotational axis, and
an image-capturing section is provided to the rotation section to be rotated integrally with the rotation section.
   (18) A holding method that is performed to provide, to a target, a substrate on which an inertial sensor is arranged, the holding method including
connecting at least two portions of the substrate to the target using a bonding structure obtained by an adhesive material being provided between the target and substrate being spaced from each other.
   (19) A holding method that is performed to provide, to a target, a substrate on which an inertial sensor is arranged, the holding method including:
connecting one of at least two portions of the substrate to the target using a pressing structure obtained by the substrate being pressed against the target to be fixed to the target; and
connecting another of the at least two portions to the target using a bonding structure obtained by an adhesive material being provided between the target and substrate being spaced from each other.

### REFERENCE SIGNS LIST

1 rotation section
5 rotational axis
7 image-capturing direction
10 inertial sensor
12 rotation drive section
13 rotation controller
16 motor
18 front holder
21 camera module
26 IMU substrate
27 substrate-use screw
29 rear holder
59 adhesive
60 IMU sensor
61 internal space
62 center of gravity
63 perpendicular
64 division plane
65 first division space
66 second division space
67 center of gravity
80 target
81 substrate
82 connection structure portion
83 bonding structure
84 pressing structure
86 insertion portion
87 through hole
88 insertion portion
89 first fixation portion
90 second fixation portion
91 elastic body
100 image-capturing apparatus
200 holding structure

1. A holding structure used to provide, to a target, a substrate on which an inertial sensor is arranged, the holding structure comprising
at least two connection structure portions that are respectively provided to at least two portions of the substrate, the at least two connection structure portions being used to connect the substrate to the target, wherein
the at least two connection structure portions each have a bonding structure obtained by an adhesive material being provided between the target and substrate being spaced from each other, or
one of the at least two connection structure portions has a pressing structure obtained by the substrate being pressed against the target to be fixed to the target, and another of the at least two connection structure portions has the bonding structure.

2. The holding structure according to claim 1, wherein
the pressing structure includes a structure obtained by the substrate being fixed to the target through a fastening member.

3. The holding structure according to claim 2, wherein
the fastening member is a screw.

4. The holding structure according to claim 1, wherein
the pressing structure includes a structure obtained by the substrate being sandwiched using the target to be fixed to the target.

5. The holding structure according to claim 4, wherein
the target includes a first fixation portion and a second fixation portion between which the substrate is sandwiched to be fixed to the target, and
at least one of the first fixation portion or the second fixation portion fixes the substrate to the target through an elastic body.

6. The holding structure according to claim 1, wherein
the bonding structure includes a structure obtained by the adhesive material being provided on a basis of a position of a hole of the target in a state in which an insertion portion of the substrate is inserted into the hole.

7. The holding structure according to claim 6, wherein
the hole is a through hole.

8. The holding structure according to claim 6, wherein
the adhesive material is provided to cover at least a portion of an opening of the hole.

9. The holding structure according to claim 6, wherein
the hole is filled with the adhesive material.

10. The holding structure according to claim 1, wherein
the bonding structure includes a structure obtained by the adhesive material being provided on a basis of a position of a hole of the substrate in a state in which an insertion portion of the target is inserted into the hole.

11. The holding structure according to claim 1, wherein
the at least two connection structure portions each have the bonding structure.

12. The holding structure according to claim 1, wherein
one of the at least two connection structure portions has the pressing structure, and
another of the at least two connection structure portions has the bonding structure.

13. The holding structure according to claim 1, wherein
the inertial sensor is configured to include at least one of an acceleration sensor or an angular velocity sensor.

14. The holding structure according to claim 1, wherein
respective positions of the at least two connection structure portions are set on a basis of a position of the inertial sensor on the substrate.

15. The holding structure according to claim 1, wherein
a position of the inertial sensor is set on a basis of respective positions of the at least two connection structure portions.

16. The holding structure according to claim 15, wherein
the inertial sensor is arranged at a center of gravity obtained by using the respective positions of the at least two connection structure portions.

17. The holding structure according to claim 1, wherein
the holding structure is configured such that the substrate is provided to a rotation section to be rotated integrally with the rotation section, the rotation section being the target, the rotation section being rotatable about a specified rotational axis, and
an image-capturing section is provided to the rotation section to be rotated integrally with the rotation section.

18. A holding method that is performed to provide, to a target, a substrate on which an inertial sensor is arranged, the holding method comprising
connecting at least two portions of the substrate to the target using a bonding structure obtained by an adhesive material being provided between the target and substrate being spaced from each other.

19. A holding method that is performed to provide, to a target, a substrate on which an inertial sensor is arranged, the holding method comprising:
connecting one of at least two portions of the substrate to the target using a pressing structure obtained by the substrate being pressed against the target to be fixed to the target; and
connecting another of the at least two portions to the target using a bonding structure obtained by an adhesive material being provided between the target and substrate being spaced from each other.
